(19) United States
(12) Patent Application Publication
(10) Pub. No.: US 2021/0293645 A1
(43) Pub. Date: Sep. 23, 2021

(54) CERAMIC BASED STRAIN DETECTOR

(71) Applicant: ARRIS Enterprises LLC, Suwanee, GA (US)

(72) Inventors: Anastacio FAVELA CARRASCO, San Nicolas de los Garza (MX); Carlos Ramon BAEZ ALVAREZ, Apodaca (MX); Alfredo Alberto DE LA LLATA AYALA, General Escobedo (MX)

(73) Assignee: ARRIS Enterprises LLC, Suwanee, GA (US)

(21) Appl. No.: 17/204,688

(22) Filed: Mar. 17, 2021

Related U.S. Application Data
(60) Provisional application No. 62/990,889, filed on Mar. 17, 2020.

(51) Int. Cl. G01L 9/04; G01L 1/18

(52) U.S. Cl. CPC G01L 9/04; G01L 1/18

(57) ABSTRACT

A ceramic based strain detector includes a ceramic body including a conductive member deposited thereon, and a pair of conductive end caps affixed to respective ends of the ceramic body. The strain detector is supported by a circuit board and fractures when the circuit board undergoes excessive strain. A strain monitor is configured to detect when the strain detector fractures by sensing a resistance between the pair of conductive end caps.

### CROSS-REFERENCE TO RELATED APPLICATIONS

This application claims benefit of U.S. Provisional Patent Application No. 62/990,889 filed Mar. 17, 2020, the entirety of which is incorporated herein by reference.

### BACKGROUND OF THE INVENTION

The present invention relates to a printed circuit board that includes a ceramic based strain detector.

Printed circuit boards mechanically support and electrically connect various electrical components using conductive traces, pads, and other features etched from one or more layers of electrically conductive material together with one or more layers of electrically dielectric material. For example, copper is often used as the electrically conductive material. Multi-layer printed circuit boards typically include two or more internal conductive layers together with an upper surface layer of conductive material, separated by the dielectric material with conductively filled holes defined therein that electrically interconnect the conductive material of the different layers together.

Circuit board manufacturing and assembly processes places stress on the circuit board components, such as from mechanical, thermal, physical, chemical, etc. sources. By way of example, printed circuit board production often uses high soldering temperatures to accommodate lead-free processes. Physical loading of the circuit board can cause damage to various components of the printed circuit board resulting in electrical and/or mechanical failure, including pad cratering which is a type of crack. By way of example, thermal stress as a result of high temperatures tends to crack solder joints of the circuit board, including pad cratering which is a type of crack. More often, pad cratering occurs during dynamic mechanical events such as mechanical shock or board flexure as a result of in-circuit testing, board depaneling, or connector insertion. In particular, pad cratering is an induced fracture in the resin between the copper and the outermost layer of dielectric of the printed circuit board or an induced fracture within the dielectric layers. In general, excessive flexing of the printed circuit board during manufacturing, shipping, or installation will cause electrical components to fail to operate properly.

Pad cratering tends to be difficult to detect during functional testing, especially in the case of small or partial cracking that may result in latent field failures. Conventional testing techniques, such as visual inspection and x-ray microscopy may not effectively detect the pad cratering. Even a testing technique based upon electrical characterization may not detect pad cratering if there is only partial cracking.

U.S. Pat. No. 6,532,824 discloses a capacitive strain sensor that includes a substrate and a pair of interdigital electrode capacitors formed on the substrate. A dielectric thick film having a uniform thickness and made of a material the dielectric constant of which varies with strain is provided on an elastic body having a flat or curved surface on the substrate. A block for preventing strain from being produced is secured to one end of the substrate and a weight is secured to the other end. The capacitors are formed by interdigitally arranging a pair of electrodes being parallel linear electrodes of linear conductors on the substrate. Unfortunately, such a capacitive strain sensor needs to be continuously sensed with a powered electronic circuit in order to detect such induced strain.

What is desired is an effective technique for detecting potential pad cratering.

The foregoing and other objectives, features, and advantages of the invention will be more readily understood upon consideration of the following detailed description of the invention, taken in conjunction with the accompanying drawings.

### BRIEF DESCRIPTION OF THE SEVERAL VIEWS OF THE DRAWINGS

FIG. 1 illustrates a printed circuit board, a package, and strain sensors.

FIG. 2 illustrates a ceramic body of the strain sensor of FIG. 1.

FIG. 3 illustrates the ceramic body and end caps of the strain sensor of FIG. 1.

FIG. 4 illustrates a fractured strain sensor of FIG. 1.

FIG. 5 illustrates fractured ceramic of a fractured strain sensor of FIG. 1.

FIG. 6 illustrates a printed circuit board, a package, strain sensors, and a strain monitor.

### DETAILED DESCRIPTION OF PREFERRED EMBODIMENT

As previously described, printed circuit board assemblies (PCBAs) are becoming more complex and susceptible to mechanical strain induced failures. Mechanical strain can cause failures during assembly, shipping, handling, and field operation. Such failures due to mechanical strain may occur in solder joints, traces, or in the circuit board itself, inclusive of pad cratering. Determining the existence of such failures, including when such failures occur, is desirable to take measures to prevent such future failures, and to repair or discard damaged printed circuit board assemblies.

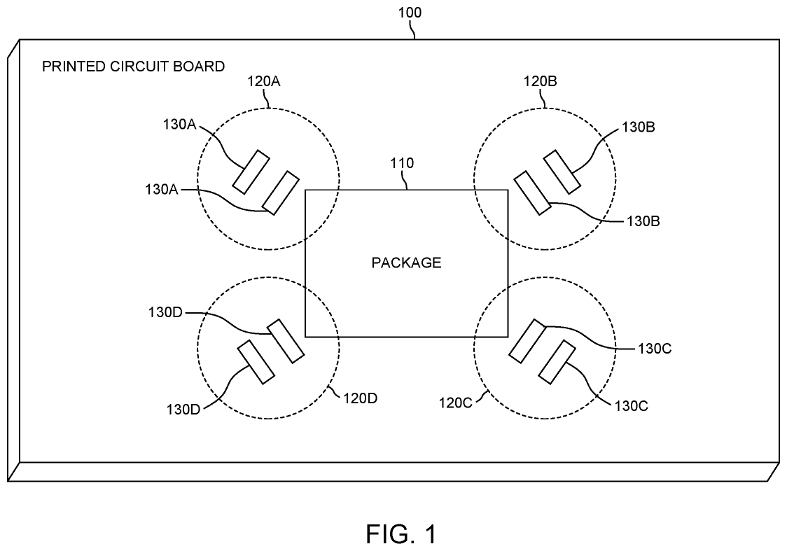

Referring to FIG. 1, a printed circuit board 100 that may include a one or more of layers of dielectric material and one or more layers of conductive material. The printed circuit board 100 supports one or more electronic circuits, typically formed as part of a package 110. The package 110 may comprise any type electronic component or circuit element capable of being supported by the printed circuit board 100, such as a ball grid array device. The printed circuit board 100, relative to the package 110, may include a plurality of sensitive high stress regions (e.g., a first high stress region 120A, a second high stress region 120B, a third high stress region 120C, and a fourth high stress region 120D) that are prone to impacting the performance of the package 110.

One or more strain detectors 130 may be supported by the upper surface of the circuit board 100. Preferably one or more strain detectors 130A is included within the first high stress region 120A. Preferably one or more strain detectors 130B is included within the second high stress region 120B. Preferably one or more strain detectors 130C is included within the third high stress region 120C. Preferably one or more strain detectors 130D is included within the fourth high stress region 120D. Often, the regions proximate the corners of a package 110 are more susceptible to damage due to straining or flexing. One or more strain detectors 130 may be located at any other suitable location on the printed circuit board 110, and preferably located in those regions that are more susceptible to damage due to straining or flexing circuit board 110.

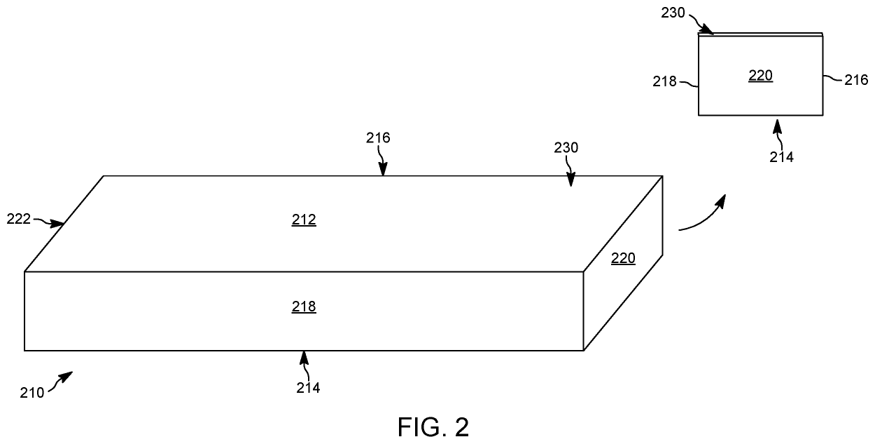

Referring to FIG. 2, an exemplary strain detector may include a ceramic body 210 that includes a planar upper surface 212, a planar lower surface 214, a planar right side 216, a planar left side 218, a planar right end 220, and/or a planar left end 222. Preferably, the ceramic body 210 has a rectangular shape, although other shapes may be used. A thin layer of conductive material 230 is deposited on the planar upper surface 212 of the ceramic body 210. The conductive material 230 preferably extends from substantially the planar right end 220 to the planar left end 222. The conductive material 230 preferably covers over a majority of the planar upper surface 212.

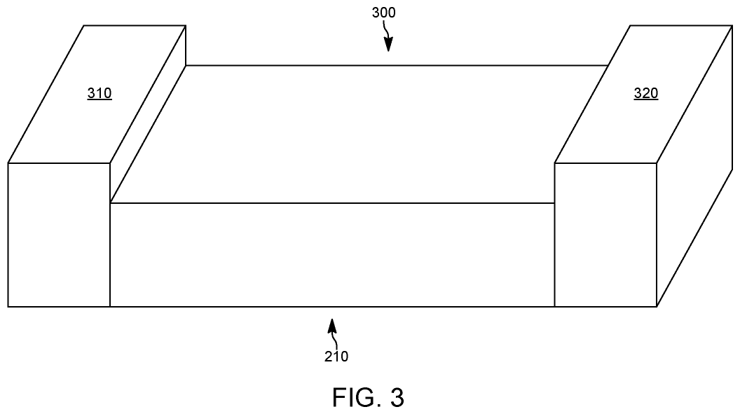

Referring to FIG. 3, an exemplary strain detector 300 includes the ceramic body 210 including the conductive material 230, together with a left end cap 310 and a right end cap 320. The left end cap 310 and the right end cap 320 sandwich the ceramic body 210 therebetween. The left end cap 310 and the right end cap 320 are preferably formed from conducive material and are each electrically interconnected to the conductive material 230. In this manner, a low resistance path exists between the left end cap 310 and the right end cap 320.

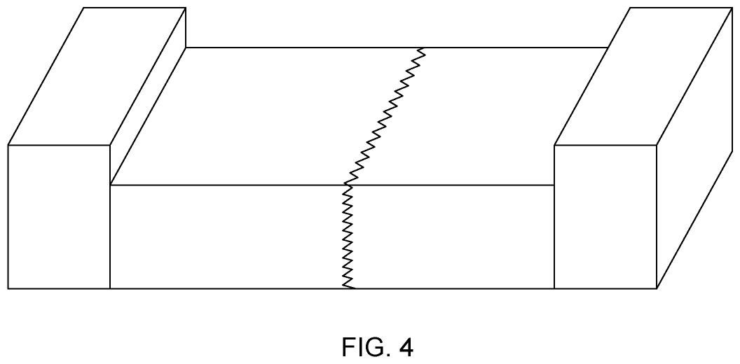

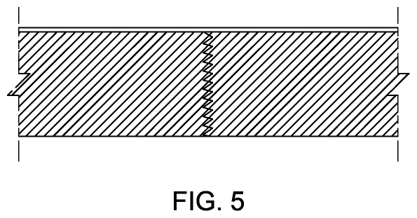

The strain detector 300 is supported by the upper surface of the printed circuit board 100 and secured thereto, such as by soldering. The particular ceramic material 210 together with its dimensions are selected such that it fractures at a specific strain imposed thereon that is consistent with the mechanical strain range of the particular printed circuit board that it is supported thereon. In other words, the ceramic body material and dimensions are selected such that it will fracture within a mechanical strain range depending on the range of strain to be detected for a particular printed circuit board. The excessive strain may be the result, for example, of assembly, of shipping, of handling, and/or of field operation. Alternatively, the ceramic body may be constructed from other materials that fracture under stress. Referring to FIG. 4, when the ceramic material 210 fractures under strain it also fractures the conductive material 230, at least to some extent, deposited thereon. Referring to FIG. 5, the ceramic material 210 fractures under strain. The fractured conductive material 230 substantially increases the electrical resistance as sensed between the left end cap 310 and the right end cap 320.

During the assembly of the package 110 on the printed circuit board 100, with the strain detectors 300 already supported thereon, the conductivity of each of the strain detectors 300 may be tested to ensure that the printed circuit board 100 has not undergone excessive strain. After shipping (to or from a customer) and/or handling and/or field operations the printed circuit board 100 with the package 110 and the strain detectors 300 supported thereon, the conductivity of each of the strain detectors 300 may be tested to ensure that the printed circuit board 100 has not undergone excessive strain. Periodically while using the printed circuit board 100 with the package 110 and the strain detectors 300 supported thereon, the conductivity of each of the strain detectors 300 may be tested to ensure that the printed circuit board 100 has not undergone excessive strain. A sufficient difference in the results of the testing will indicate when such an excessive strain occurred.

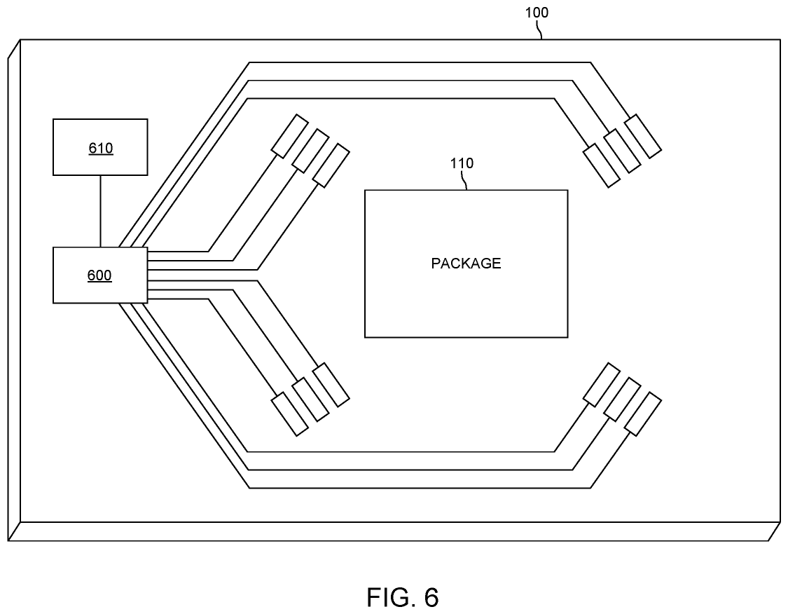

Referring to FIG. 6, while the strain detectors 300 may be manually tested using an external testing device connected to the ends thereof, the strain detectors 300 are preferably electrically interconnected to a strain monitor 600 that may include an associated battery 610 that periodically senses the resistance of each of the strain detectors to determine if the printed circuit board 100 has undergone excessive strain. In the event that the strain monitor 600 detects that the printed circuit board 100 has undergone excessive strain an output signal may be provided, such as through a network connection or a visual signal (e.g., LED light). It is also noted that the capturing of an excessive strain event by the ceramic material occurs independently of whether or not the strain monitor or any other circuit is operating or otherwise has power provided thereto.

By way of example, the strain sensor may be approximately 1 mm (or less) by 2 mm (or less) in size with a ceramic thickness of approximately 50-300 micrometers and with a conductive material thickness of a few micrometers (e.g., less than 10 micrometers). For example, the strain sensor may have approximately 0-5 ohms of resistance prior to fracture. For example, the strain sensor may have approximately 10 ohms of resistance (or more) after fracture. Preferably, the change in resistance is greater than 2×, and/or greater than 20 ohms. Further, the alarm circuit 600 may store the pre-fracture resistance(s) so that if a substantial change from the pre-fracture resistance occurs, it may be readily determined. If desired, the testing may occur shortly before shipment of the product to a customer, then may be testing may occur after shipment to the customer, to determine if an overstress occurred during transportation and/or during the life at the customer.

While this specification contains many specific implementation details, these should not be construed as limitations on the scope of any invention or of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a sub combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

The terms and expressions which have been employed in the foregoing specification are used therein as terms of description and not of limitation, and there is no intention, in the use of such terms and expressions, of excluding equivalents of the features shown and described or portions thereof, it being recognized that the scope of the invention is defined and limited only by the claims which follow.

I/we claim:

1. An apparatus comprising:
(a) a circuit board;
(b) a strain detector including a fracturable body including a conductive member deposited thereon;
(c) said strain detector including a pair of conductive end caps affixed to respective ends of said fracturable body;
(d) said strain detector supported by said circuit board and configured such that said fracturable body fractures when said circuit board undergoes excessive strain;
(e) a strain monitor configured to detect when said strain detector fractures by sensing a resistance between said pair of conductive end caps.

2. The apparatus of claim 1 wherein said circuit board is a printed circuit board.

3. The apparatus of claim 1 wherein said fracturable body is rectangular.

4. The apparatus of claim 1 wherein said fracturable body is less than 300 micrometers thick.

5. The apparatus of claim 1 wherein said fracturable body has a length less than 2 mm.

6. The apparatus of claim 1 wherein said fracturable body has a width less than 1 mm.

7. The apparatus of claim 1 wherein said conductive material covers an entire upper surface of said fracturable body.

8. The apparatus of claim 1 wherein said conductive material covers at least a majority of an upper surface of said fracturable body.

9. The apparatus of claim 1 wherein said conductive material also fractures together with said fracturable body.

10. The apparatus of claim 1 wherein said conductive material is less than 10 micrometers thick.

11. The apparatus of claim 1 wherein said strain monitor senses a change in resistance of said resistance between said pair of conductive end caps.

12. The apparatus of claim 1 wherein said change in resistance is greater than 2 times to indicate said fracture.

13. The apparatus of claim 1 wherein said strain monitor senses at least 10 ohms to indicate said fracture.
